(19) United States
(12) Patent Application Publication
(10) Pub. No.: US 2008/0032139 A1
(43) Pub. Date: Feb. 7, 2008

(54) Substrate For Electronic Application, Including A Flexible Support And Method For Production Thereof

(76) Inventors: Gilles Le Blevennec, Bernin (FR); Philippe Prene, Tours (FR)

Correspondence Address: THELEN REID BROWN RAYSMAN & STEINER LLP, P. O. BOX 640640, SAN JOSE, CA, 95164-0640, US

(21) Appl. No.: 11/597,818

(22) PCT Filed: May 26, 2005
(86) PCT No.: PCT/FR05/50373

§ 371 Date: Nov. 22, 2006

(30) Foreign Application Priority Data
May 27, 2004 (FR) 04 51045

(51) Int. Cl. B32B 9/04; H01L 21/20

(52) U.S. Cl. 428/446; 438/479; 257/E21.09

(57) ABSTRACT

The invention relates to a substrate for electronic use including a flexible support covered successively by a porous oxide layer and a polycrystalline or amorphous silicon layer. The invention also relates to a method for producing such a substrate.

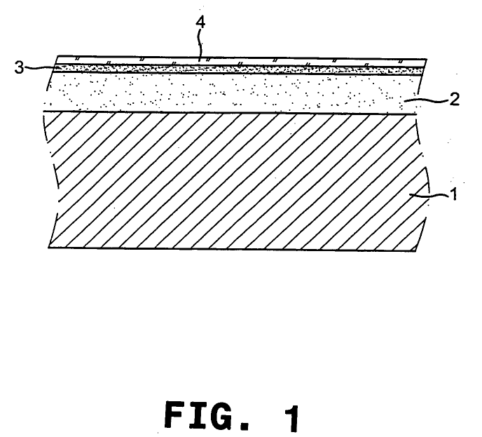

### TECHNICAL FIELD

This invention relates to a substrate for electronic application, including a flexible support. This substrate may be intended to be used for organic or inorganic electronics. The invention also relates to the method for production thereof.

Among the possible applications of this substrate, the following fields can be cited:

flat-panel display screens, televisions, computers;

flexible screens for telephones or nomadic electronic objects, video games;

smart tags (cold chain tracer, marking, identification);

radiofrequency identification systems (RFID), remote reading, automatic billing;

memory cards, smart cards, circuits on a thin and flexible support;

sensors, fingerprint readers;

biosensors, electronic systems associated with DNA chips (or “biochip”);

supports for photovoltaic cells;

supports for low-cost electronics for large surface applications;

electronic book or paper (or “e-book”).

### PRIOR ART

Providing electronics over large surfaces is a necessity in particular for manufacturers of display screens. Indeed, for a liquid crystal display (LCD) or a screen with organic light-emitting diodes (OLED) to function, it is necessary to have an electronic circuit on the rear side in order to control the pixels (or image elements) of the screen. Today, these electronics are produced using a technology on glass where amorphous silicon is deposited at low temperature. This low-performance amorphous silicon is used to produce transistors on the rear surface of the screen. This activity is particularly advanced today and is quickly evolving toward a so-called polycrystalline silicon technology. This technology consists of crystallising the amorphous silicon so as to enhance its electronic properties and allow for the production of more high-performing circuits for controlling screens.

It is an objective for many manufacturers to develop this technology toward flexible substrates, which replace glass. It would be beneficial to find an inexpensive, non-fragile and possibly “conformable” substrate, i.e. a substrate that can fit on non-planar and even flexible surfaces.

Many recent studies concern plastic substrates.

The article “A conformable Electronic Ink Display using a Foil-Based a-Si TFT Array” by Y. CHEN et al., published in SID 01 Digest, pages 157-159, discloses the production of thin film transistors and capacitances on an amorphous silicon layer deposited on a stainless steel sheet. This article mentions the deposition of a passivation layer on the pre-polished metal sheet. This article does not disclose the composition of this passivation layer or the deposition technique used.

Other articles disclose different productions of transistors on metal sheets. The following can be cited:

“Amorphous Silicon Thin Film Transistors on Steel Foil Substrates” by S. D. THEISS and S. WAGNER, IEEE Electron Device Letter, Vol. 17, 1999, pages 578-580;

“Flexible, Lightweight Steel Foil Substrates for Amorphous Silicon Thin Film Transistors” by S. D. THEISS and S. WAGNER, SID AM-LCD 96 Tech. Dig., 1996, pages 365-368;

“Complementary Metal-Oxide-Semiconductor Thin-Film Transistor Circuits from a High-Temperature Polycrystalline Silicon Process on Steel Foil Substrates” by Ming W U et al., Vol. 49, No. 11, November 2002.

These articles describe the feasibility of the production of transistors on amorphous or polycrystalline silicon using a flexible or rigid metal substrate. However, the deposition of passivation layers between the silicon layer and the metal sheet is always performed by a vacuum technique, primarily PECVD (for “Plasma Enhanced Chemical Vapor Deposition”). PECVD requires a vacuum for the samples and heating at 300° C. in order to obtain a passivation layer having the required properties. In addition, the layers obtained are dense, which makes them breakable.

### DESCRIPTION OF THE INVENTION

This invention proposes a method for producing a substrate for electronic use including a flexible support and a passivation layer deposited by a cold method.

The invention therefore relates to a substrate for electronic use including a flexible support covered successively with an electrically insulating layer and a layer of amorphous or polycrystalline silicon, characterised in that the electrically insulating layer is a porous oxide layer.

The porous oxide layer provides electrical insulation with respect to the flexible support. It serves as a buffer layer in order to attenuate the mechanical stresses that may be conferred upon the silicon layer. It also makes it possible to obtain mechanical flexibility of the stack produced. The porous structure makes it possible, by virtue of its capacity to be deformed, to tolerate bending or extending of the support. It also serves as a primer layer for the silicon.

The substrate can also advantageously include a levelling layer inserted between the porous oxide layer and the amorphous or polycrystalline silicon layer. This levelling layer can be a dense oxide layer. The dense oxide (for example, silica) also serves as a chemical barrier against any contaminants that may come from a metal portion of the support by passing through the porous oxide layer.

The support can be chosen from the group consisting of a plastic sheet, a paper sheet, a flexible metal sheet and a flexible metal strip. It can be made of stainless steel. As an advantageous example, the metal sheet or the metal strip is made of a material of which the thermal dilation coefficient is similar to that of silicon.

If the support is a plastic or paper sheet, it can include at least one metal track.

The oxide of the porous metal layer can be chosen from among the metal or metalloid oxides SiO₂, TiO₂, Ta₂O₅, Al₂O₃, ZrO₂, HfO₂ and MgO.

The invention also relates to a method for producing a substrate for electronic use, including the following steps:

providing a flexible support,

depositing, on the support, a porous oxide layer by a sol-gel technique,

depositing, on the porous oxide layer, an amorphous silicon layer.

The method can also include a step of transforming the amorphous silicon into polycrystalline silicon.

The deposition of the porous oxide layer by a sol-gel technique is particularly advantageous for the applications envisaged by the invention. It is a wet process deposition that can be performed on objects by dip coating or by roller coating. There is no need for the vacuum, and this technique can be implemented in a line or by rolling.

The amorphous silicon layer can be deposited by a PECVD technique or a spray technique. It should be noted that it would be advantageous to deposit the amorphous or polycrystalline silicon layer by a sol-gel technique.

The transformation of the amorphous silicon into polycrystalline silicon can be performed by means of a UV laser beam or by SPC (for “Solid Phase Crystallization”) in a suitable oven.

The method can include, between the step of deposition of the porous oxide layer and the step of deposition of the amorphous silicon layer, a step of deposition of a levelling layer on the porous oxide layer. The levelling layer is advantageously a dense oxide layer.

### BRIEF DESCRIPTION OF THE DRAWINGS

The invention can be better understood and other advantages and features will become clearer from the following description provided by way of a non-limiting example, accompanied by the appended drawing, which is a transverse cross-section view of a substrate for electronic use according to the invention.

### DETAILED DESCRIPTION OF SPECIFIC EMBODIMENTS

The appended drawing is a transverse cross-section view of a substrate for electronic use according to the present invention.

The substrate includes a flexible support 1, i.e. a support capable of having at least one curve, for example, a flexible metal sheet. The substrate is chosen so that its bending properties are compatible with the envisaged application. The material of the metal sheet can also be chosen so as to have a thermal dilation coefficient that is low or compatible with the thermal dilation coefficient of silicon: 4.2×10⁻⁶ K⁻¹. This metal material can be invar (registered trademark) with the formula Fe₆₄Ni₃₆, which has a thermal dilation coefficient of 1.7 to 2×10⁻⁶ K⁻¹. Other alloys may also be suitable. Stainless steel can advantageously be used because it has good bending properties and is compatible with high temperatures.

The support is preferably metal. However, it can also be made of an insulating material, for example plastic (such as a polyimide) or paper, and may or may not include metal conductive tracks. It can also be made of a semiconductor material and may or may not include metal conductive tracks. This support must be relatively dense and compatible with the subsequent technological steps. It must in particular not be too rough on the surface. It can, as necessary, be coated with an antioxidant layer (for example a dense SiO₂ layer) in order to protect it during subsequent technological steps.

A porous oxide layer such as porous silica 2 is deposited on the support 1 by a sol-gel technique. This is a technique that is performed in solution by wet processing and that synthesizes electronic quality materials.

For the sol-gel process, by oxide precursors, we are referring in the invention to alkoxide compounds of formula M (OR)ₙ with M representing a metal element or a metalloid element as defined above, R representing an alkyl group including 1 to 6 carbon atoms, n representing the valence of the metal element or the metalloia element, wherein the alkoxide can be replaced by a mineral precursor (metal salt) or any other metal or metalloid element molecular precursor capable of being hydrolysed.

According to the invention, the solution deposited onto the support is obtained according to the polymerisation technique by the “sol-gel” process, which is short for “solution-gelatine”.

According to this sol-gel technique, the aforementioned solution is synthesized, generally by mixing one or more precursors as defined above in a medium including at least one organic or aqueous solvent followed by complete or partial hydrolysis of said precursors and condensation of said precursors thus hydrolysed.

The organic solvent(s) in which the semiconductor oxide precursors are mixed are generally alcoholic solvents, in particular aliphatic alcohols, such as ethanol or isopropanol.

The hydrolysis of the precursors is generally obtained by adding an aqueous solution (acid, base or neutral) to the mixture. Once hydrolysed, the precursors have reactive groups, such as —OH, capable of being condensed in a condensation step, at the end of which the solution contains chemical species in the form of oligomers, polymers or colloids.

A person skilled in the art will choose, depending on the nature of the precursors, the conditions for hydrolysis (pH, amount of water added, etc.) of these precursors so as to obtain, in the solution, chemical species in the form of oligomers, polymers or colloids.

This technique can include a step of dip coating and/or spin coating and/or spray coating and/or soak coating and/or roll-to-roll process and/or paint coating and/or screen-printing, as is known to a person skilled in the art.

The porous oxide layer can ensure electrical insulation with respect to the support if the latter is metal. A porous silica layer typically with a thickness of 1 to 5 μm enables parasitic capacitance phenomena to be avoided.

By porous layer, we are referring to a layer capable of allowing for the passage of a gas and/or a layer containing bubbles (empty, gas or liquid). It makes it possible to confer a certain flexibility on the layer. The oxide can be a metal or metalloid oxide such as, for example, MgO, SiO₂, ZrO₂, Al₂O₃, TiO₂, Ta₂O₅, and HfO₂.

By metal oxide, we are referring in the invention to an oxide having, in its crystal or amorphous lattice, one or more metal elements. These metal elements can be transition metals or lanthanide metals, such as those defined below. The metal transition element can be chosen from Ti, V, Cr, Mn, Fe, Co, Ni, Cu, Zn, Y. Zr, Nb, Mo, Ru, Rh, Pd, Ag, Cd, Hf, Ta, W, Re, Os, Ir and Pt. The lanthanide element can be chosen from La, Ce, Pr, Nd, Sm, Eu, Gd, Tb, Dy, Er and Yb. The metal elements can also be so-called post-transitional metals, such as those belonging to column IIIA (Al, Ga, In, Tl) and column IVA (Ge, Sn, Pb) of the periodic table of elements.

By metalloid oxide, we are referring in this invention to an oxide having, in its crystal lattice one or more metalloid elements, said metalloid elements being selected from Si, Se and Te.

All of these materials are compatible with a sol/gel deposit. They are refractory. By adjusting the refractory character as well as the thickness of this layer, it is possible to make the underlying support compatible with certain technological steps, and in particular laser recrystallization or SPC of the amorphous silicon. They are also insulating.

The porous oxide layer 2 can serve as a primer layer for the silicon. Depending on the targeted applications, a planarity or levelling layer can be deposited on the porous silica layer in order to provide the most planar surface possible. This planarity layer can be a thin film (so as to preserve the flexibility) but dense so as to obtain planarity and seal the pores. In the appended drawing, reference 3 designates a dense silica layer of one hundred to several hundred nanometres deposited on the porous silica layer 2. The dense silica layer 3 can be deposited by PECVD, but advantageously by a sol/gel technique.

An amorphous silicon layer 4 is then deposited onto the dense silica layer 3. The layer 4 can have a thickness of between 30 and 150 nm. The deposition thereof can be performed by PECVD at a temperature of between 150° C. and 330° C.

The amorphous silicon is then crystallised so as to produce polycrystalline silicon, for example by means of a UV laser beam or SPC in a suitable oven at a typical temperature of 900° C.

The substrate according to this invention can advantageously replace the glass support substrates used for display panels. It includes a thinner, cheaper support that is available in a thin sheet with a thickness lower than 100 μm.

The stack obtained ensures good mechanical strength. The substrate does not break, unlike glass support substrates. It can conform to non-planar surfaces. It remains stable at the high temperatures for producing inorganic TFT transistors.

The metal support of the substrate according to the invention advantageously has good heat conductivity, which allows for the release of calories produced by the electronic produced on the substrate. It can also serve as a ground plane, with the production of a contact through the insulating layer.

The stack can have relatively low thermal dilation coefficients, which makes it possible to prevent any distortions when producing circuits through the silicon layer.

All of the steps for preparing the substrate, at least until the silicon deposition, can be performed, in the state of the art, by rolling using low temperature techniques, without placing the materials in a vacuum. The deposition is performed by wet processing. Everything is done at atmospheric pressure.

The substrate is compatible with all technologies for producing polycrystalline or amorphous silicon circuits. This technology is currently used for flat liquid crystal displays. The substrate will withstand in particular the temperatures of the various processes, which are currently at 500° C. It can even, depending on the substrate used (this is the case for stainless steel), withstand higher temperatures and thus make higher performing treatments possible, such as SPC recrystallization and the thermal oxide production.

The substrate is compatible with the techniques for crystallisation of silicon by laser.

This substrate is also compatible with the technologies for producing circuits based on organic components.

1. Substrate for electronic use including a flexible support and covered successively by an electrically insulating layer and a polycrystalline or amorphous silicon layer, wherein the electrically insulating layer is a porous oxide layer, thus making the substrate flexible, said silicon layer having a free surface.

2. Substrate according to claim 1, wherein it also includes a levelling layer inserted between the porous oxide layer and the amorphous or polycrystalline silicon layer.

3. Substrate according to claim 2, wherein the levelling layer is a dense oxide layer.

4. Substrate according to claim 1, wherein the support is chosen from the group consisting of a plastic sheet, a paper sheet, a flexible metal sheet and a flexible metal strip.

5. Substrate according to claim 4, wherein the support is made of stainless steel.

6. Substrate according to claim 4, wherein the metal sheet or the metal strip is made of a material of which the thermal dilation coefficient is similar to that of silicon.

7. Substrate according to claim 1, wherein the support is a plastic sheet or a paper sheet, which support includes at least one metal track.

8. Substrate according to claim 1, wherein the oxide of the porous oxide layer is chosen from the metal or metalloid oxides TiO₂, Ta₂O₅, Al₂O₃, ZrO₂, HfO₂ and MgO.

9. Substrate according to claim 1, wherein the oxide of the porous layer is SiO₂.

10. Method for producing a flexible substrate for electronic use, includes the following steps:
providing a flexible support,
depositing, on the support, a porous oxide layer by a sol-gel technique, said deposit thus making the substrate flexible,
depositing, on the porous oxide layer, an amorphous silicon layer, an amorphous silicon layer having a free surface.

11. Method according to claim 10, wherein it also includes a step of transforming the amorphous silicon into polycrystalline silicon.

12. Method according to claim 10, characterised in that wherein the step of providing a support consists of providing a support chosen from the group consisting of a plastic sheet, a paper sheet, a flexible metal sheet and a flexible metal strip.

13. Method according to claim 12, wherein the metal sheet or the metal strip is made of a material of which the thermal dilation coefficient is similar to that of silicon.

14. Method according to claim 10, wherein the support being a plastic sheet or a paper sheet, said support includes at least one metal track.

15. Method according to claim 10, wherein the deposition of the porous oxide layer includes a step of dip coating or roller coating.

16. Method according to claim 10, wherein the amorphous silicon layer is deposited by a PECVD technique or a spray technique.

17. Method according to claim 11, characterised in that wherein the transformation of the amorphous silicon into polycrystalline silicon is performed by means of a UV laser beam.

18. Method according to claim 10, including between the step of deposition of the porous oxide layer and the step of deposition of the amorphous silicon layer, a step of deposition of a levelling layer on the porous oxide layer.

19. Method according to claim 18, wherein the levelling layer is a dense oxide layer.

20. Method according to claim 10, wherein the oxide of the porous oxide layer is chosen from SiO₂, TiO₂, Ta₂O₅, Al₂O₃, ZrO₂ and HfO₂.
